(19) United States
(12) Patent Application Publication
(10) Pub. No.: US 2026/0039279 A1
(43) Pub. Date: Feb. 5, 2026

(54) LATCH-BASED FINITE IMPULSE RESPONSE FILTER

(71) Applicant: STMicroelectronics International N.V., Geneva (CH)

(72) Inventors: Ankur BAL, Greater Noida (IN); Prince, Charkhi Dadri (IN)

(73) Assignee: STMicroelectronics International N.V., Geneva (CH)

(21) Appl. No.: 19/277,147

(22) Filed: Jul. 22, 2025

Related U.S. Application Data
(60) Provisional application No. 63/677,246, filed on Jul. 30, 2024.

(51) Int. Cl. H03H 17/02; H03H 17/00; H03K 3/037

(52) U.S. Cl. CPC H03H 17/02; H03K 3/037; H03H 2017/0081

(57) ABSTRACT

Provided is a filter that includes a plurality of filter stages that are serially coupled. Each filter stage of the plurality of filter stages includes a plurality of latches. The plurality of latches are respectively driven by a plurality of clock signals. The plurality of clock signals are different from each other. Each filter stage includes a flip flop coupled to a last latch of the plurality of latches. The flip flop and the last latch are driven by a first clock signal of the plurality of clock signals.

### BACKGROUND

### Technical Field

This application is directed to a latch-based finite impulse response (FIR) filter and, in particular, an FIR filter that uses more latches than flip flops.

### Description of the Related Art

Finite impulse response (FIR) filters are used in signal processing. FIR filters use memory components (e.g., shift registers) to drive computation logic. The power consumption of FIR filters is a contributor to device power consumption. Reducing the power consumption of FIR filters aids in reducing overall device power consumption.

### BRIEF SUMMARY

Provided is a latch-based FIR filter. The FIR filter may be implemented using a smaller area than conventional flip flop-based filters. The data path of the filter is aligned with multiple clock phases that are used to input data to the FIR filter computation stages (filter stages). The FIR filter has flip flop sparsely inserted therein to mitigate “shoot though.”

### BRIEF DESCRIPTION OF THE SEVERAL VIEWS OF THE DRAWINGS

FIG. 1 shows a circuit diagram of an FIR filter.

FIG. 2 shows a timing diagram of the filter.

FIG. 3 shows a system including a data source and the filter.

### DETAILED DESCRIPTION

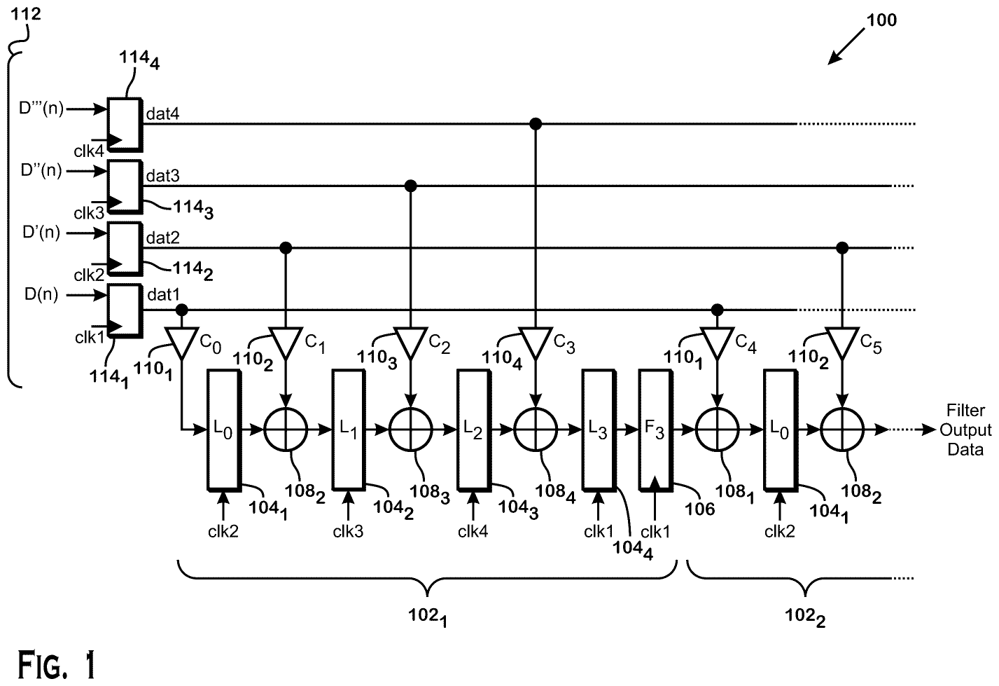

FIG. 1 shows a circuit diagram of an FIR filter 100. The filter 100 includes a plurality of filter stages 102₁₋ₙ of which a first filter stage 102₁ and a second filter stage 102₂ are shown in FIG. 1. A filter stage 102ᵢ (where i represents an index) includes a plurality of latches 104₁₋ₘ. A number of the latches (m) in the stage 102ᵢ may be the same as a decimation factor of the filter 100 as described herein. The filter 100 of FIG. 1 is shown to include filtering stages that include four latches; a first latch 104₁, a second latch 104₂, a first third latch 104₃, a fourth latch 104₄. It is noted that a last filter stage 102ₙ of the plurality of filter stages 102₁₋ₙ may include fewer than m latches. The filter stage 102ᵢ also includes a flip flop 106, a plurality of adders 108₁₋ₘ and a plurality of coefficient multipliers 110₁₋ₘ.

The filter 100 includes a loading stage 112. The loading stage 112 includes a plurality of flip flops 114₁₋ₘ. Although the loading stage 112 is shown to include four flip flops 114₁₋₄ in FIG. 1, the loading stage 112 may have any number of flip flops. Each flip flop of the plurality of flip flops 114₁₋ₘ has a data input, a clock input and a data output. The first flip flop 114₁ of the plurality of flip flops 114₁₋ₘ receives first input data (D(n)) over the data input, a first clock signal (clk1) over the clock input and output first output data (dat1) over the data output. The second, third and fourth flip flops 114₂₋₄ receive second, third and fourth input data (D′(n), D″(n), D′″(n)), respectively, and second, third and fourth clock signals (clk2, clk3, clk4), respectively, and output second, third and fourth output data (dat2, dat3, dat4), respectively.

The plurality of coefficient multipliers 110₁₋ₘ have respective inputs and respective outputs. The inputs of the plurality of coefficient multipliers 110₁₋ₘ are respectively coupled to the data outputs of the plurality of flip flops 114₁₋ₘ. A coefficient multiplier 110ᵢ multiplies received data by a coefficient (Cᵢ₋₁) and outputs a resulting product. It is noted that the coefficients of different coefficient multipliers of the filter 100 may be different. For example, the filter 100 may have 33 coefficient multipliers in nine filtering stages, whereby eight filtering stages may each have four coefficient multipliers and a ninth filtering stage may have one coefficient multiplier. The coefficients of the 33 coefficient multipliers may be the same, different from each other or have any pattern, such a symmetrical pattern.

The plurality of adders 108₁₋ₘ of a filtering stage 102 each include a primary input, a secondary input and an output. The primary input of an adder 108ᵢ is coupled to an output of a respective coefficient multiplier 110ᵢ.

In a filter stage 102ᵢ, each latch 104ᵢ and each flip flop 106 has a data input, a data output and a clock input. Except for the first latch 104₁ of the first filter stage 102₁, each latch 104ᵢ is also associated with an adder 108ᵢ that feeds the data input of the latch 104ᵢ. In particular, the data input of the first latch 104₁ of the first filter stage 102₁ is coupled to the output of the first coefficient multiplier 110₁ of the first filter stage 102₁. The data inputs of remaining latches 104ᵢ are coupled to the outputs of the coefficient multipliers 110ᵢ, respectively. Latches 104₁₋ₘ₋₁ have data outputs that are coupled to the secondary inputs of the coefficient multipliers 110₂₋ₘ, respectively. Latch 104ₙ, on the other hand, has a data output that is coupled to the data input of the flip flop 106 of the same stage 102ᵢ. The data output of the flip flop 106 is coupled to secondary input of the first coefficient multiplier 110₁ of the succeeding filter stage 102ᵢ₊₁ of the chain.

Whereas the first, second, third and fourth flip flops 114₁₋₄ are driven by the first, second, third and fourth clock signals (clk1, clk2, clk3, clk4), respectively, the order of the clock signals that drive the first, second, third and fourth latches 104₁₋₄ and the flip flop 106 of the filter stage 102ᵢ differs in relation to the position of the latches and flip flop. The flip flop 106 and last latch 104ₙ (the fourth latch 104₄ in FIG. 1) are driven by the first clock signal (clk1). Latches 114_{n-1, n-2 . . . 1} are driven in reverse order by the remaining clock signals. As shown in FIG. 1, the third latch 104₃ is driven by the fourth clock signal (clk4), the second latch 104₂ is driven by the third clock signal (clk3) and the second latch 104₂ is driven by the second clock signal (clk2). As described herein, the active time of the active time of the first clock signal (clk1) precedes the active time of the second clock signal (clk2) by a period of a fractional clock signal. Similarly, the active time of the active time of the second clock signal (clk2) precedes the active time of the third clock signal (clk3) by the period of the fractional clock signal and the active time of the active time of the third clock signal (clk3) precedes the active time of the fourth clock signal (clk4) by the period of the fractional clock signal.

A flip flop is an edge-triggered device. The flip flop receives data (e.g., a bit) over its data input. The flip flop receives a clock signal over its clock input. The flip flop outputs, over its data output, the data received over the data input at the rising edge of the clock signal (or the falling edge of the clock signal if the flip flop is a falling edge-triggered device). The flip flop retains the same output data until the next rising edge of the clock (or the falling edge if the flip flop is falling edge-triggered), irrespective of changes in the input data.

A latch also receives data (e.g., a bit) over its data input, receives a clock signal over its clock input and outputs, over its data output, the data received over the data input. A latch on the other hand is a level-triggered device. A latch is transparent when the clock signal is active (e.g., high, asserted or logical one) and opaque when the clock signal is inactive (e.g., low, deasserted or logical zero). When the clock signal is active, the latch reflects the input data at its output. For example, when the clock signal is active, the latch reflects in the output data the changes that occur in the input data. However, the latch ceases to do so when the clock signal becomes inactive. When the clock signal becomes inactive, the latch holds the most-recently output data without changing the output data to reflect changes in the input data.

Compared to a flip flop, a latch consumes less power and also requires fewer components to implement. For example, a flip-flop may be realized using two latches that are coupled in a primary-secondary configuration.

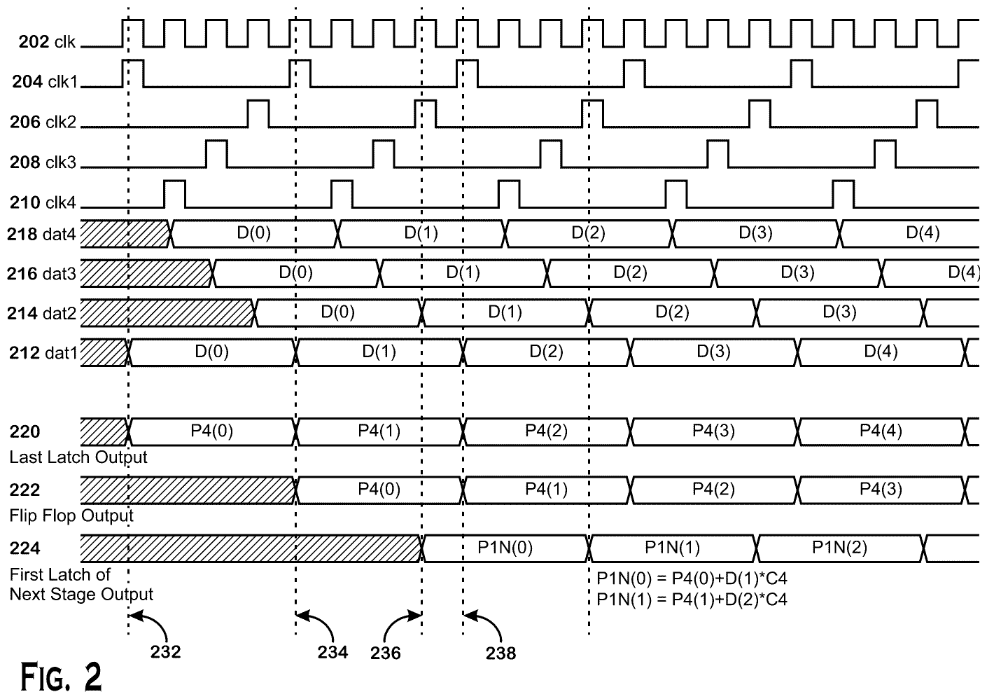

FIG. 2 shows a timing diagram of the filter 100. The timing diagram shows the fractional clock signal 202, the first, second, third and fourth clock signals (clk1, clk2, clk3, clk4) 204, 206, 208, 210 and the first, second, third and fourth output data (dat1, dat2, dat3, dat4) 212, 214, 216, 218 that are output by the flip flops of the loading stage 112. The timing diagram also shows the output data 220 of the last latch 104ₙ (the fourth latch 104₄ in FIG. 1) of the first filter stage 102₁ and the output data 222 of the flip flop 106 of the first filter stage 102₁. Both the last latch 104ₙ and the flip flop 106 are driven by the first clock signal (clk1) 204. The timing diagram also shows the output data 224 of the first latch 104₁ of the subsequent filter stage (second filter stage) 102₂. The first latch 104₁ is driven by the second clock signal (clk2) 206.

The fractional clock signal 202 is used to derive the first, second, third and fourth clock signals (clk1, clk2, clk3, clk4) 204, 206, 208, 210. Each clock signal (clk1, clk2, clk3, clk4) 204, 206, 208, 210 is active for an active duration a respective active duration of the fractional clock signal 202 over the course of m clock cycles of the fractional clock signal 202. Otherwise, the clock signals (clk1, clk2, clk3, clk4) 204, 206, 208, 210 are inactive. The active duration of the first, clock signal (clk1) 204 precedes the active duration of the fourth clock signal (clk4) 210, which precedes the active duration of the third clock signal (clk3) 208, which precedes the active duration of the second clock signal (clk2) 206.

Thus, over the course of m clock cycles (e.g., between a first time instance 232 and a second time instance 234) of the fractional clock signal 202, the plurality of flip flops 114₁₋ₘ load data (D(0)) onto the filter stages 102₁₋ₙ. The data (D(0)) may be four bits with each bit being output by a respective flip flop. Each bit remains loaded for m clock cycles of the fractional clock signal 202.

To prevent the shoot through of data from the last latch 104ₙ (the fourth latch 104₄) of the first filter stage 102₁ to the first latch 104₁ of the second filter stage 102₂, the flip flop 106 is positioned in the chain between the two latches. The flip flop 106 is also driven by the same clock signal (first clock signal (clk1) 204) as the last latch 104ₙ (the fourth latch 104₄) of the first filter stage 102₁. Accordingly, at the second time instance 234, the flip flop 106 outputs the data provided by the last latch 104ₙ (the fourth latch 104₄). At a third time instance 236 when the second clock signal (clk2) 206 becomes active, the first latch 104₁ of the second filter stage 102₂ outputs data reflecting the data provided by the last latch 104ₙ (the fourth latch 104₄). At the third time instance 236, the first latch 104₁ of the second filter stage 102₂ outputs P1N(0)=P4(0)+D(1)*C₄.

It is noted that the clock signals (clk1, clk2, clk3, clk4) 204, 206, 208, 210 activate the plurality of latches 104₁₋ₘ in reverse order from last to first in the chain. At a next clock cycle of the first clock signal (clk1) 204, the flip flop 106 is loaded with prior data whereas the last latch 104ₙ (the fourth latch 104₄) is loaded with new data.

The use of latches in the filter 100 results in both dynamic power savings and register latch savings. A conventional 64 tap FIR filter uses 64 flip flops. Given that a flip flop may be implemented using two latches, the 64 flip flops are equivalent to 128 latches. A 64-tap filter as described herein uses a total 96 latches, which amounts to a reduction of 25%. The filter 100 may be a transpose FIR filter.

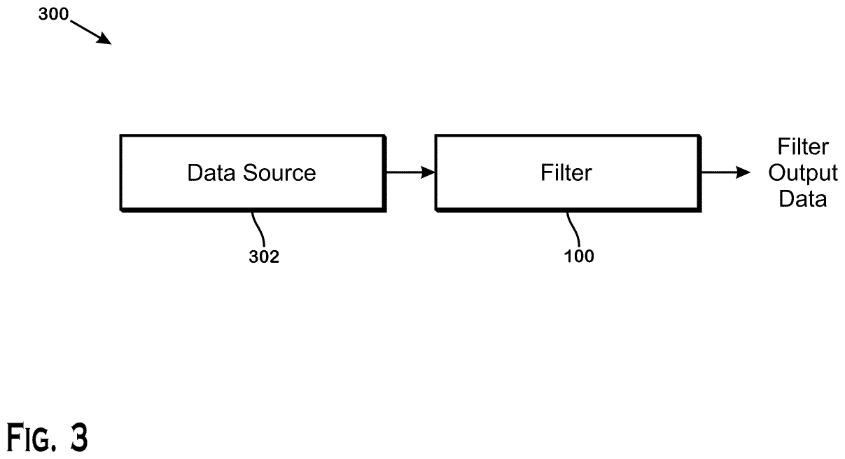

FIG. 3 shows a system 300 including a data source 302 and the filter 100. The system 300 may be an analog frontend (AFE). The data source 302, which may be an analog-to-digital converter (ADC), outputs data to the filter 100. The filter 100 filters the data as described herein to generate filter output data.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A filter comprising:
a plurality of filter stages that are serially coupled, wherein each filter stage of the plurality of filter stages includes:
a plurality of latches respectively driven by a plurality of clock signals, wherein the plurality of clock signals are different from each other; and
a flip flop coupled to a last latch of the plurality of latches, wherein the flip flop and the last latch are driven by a first clock signal of the plurality of clock signals.

2. The filter of claim 1, wherein each filter stage of the plurality of filter stages includes:
a plurality of coefficient multipliers respectively associated with the plurality of latches.

3. The filter of claim 2, wherein a coefficient multiplier of the plurality of coefficient multipliers multiplies data received over a primary input by a coefficient.

4. The filter of claim 1, wherein each filter stage of the plurality of filter stages includes:
a plurality of adders associated with the plurality of latches, respectively.

5. The filter of claim 4, wherein an adder of the plurality of adders, associated with a latch of the plurality of latches, is configured to:
add an output of a preceding latch of the plurality of latches and primary input data to generate a sum; and
provide the sum to the latch associated with the adder.

6. The filter of claim 1,
wherein the plurality of latches include:
a first latch driven by a second clock signal,
the last latch, and
an intervening latch between the first latch and the last latch, the intervening latch being driven by a third clock signal, and
wherein an active time of the first clock signal is ahead of an active time of the second clock signal by a period of a fractional clock signal, and the active time of the second clock signal is ahead of an active time of the third clock signal by the period of the fractional clock signal.

7. The filter of claim 1, comprising:
a loading stage including:
a plurality of flip flops driven by the plurality of clock signals, respectively, wherein the plurality of flip flops load parallel data received by the plurality of flip flops to a plurality of coefficient multipliers.

8. A method, comprising:
driving a plurality of latches, of a filter stage of a plurality of filter stages of a filter, using a plurality of clock signals that are different from each other, wherein the plurality of filter stages are serially coupled, driving the plurality of latches including driving a last latch of the plurality of latches using a first clock signal of the plurality of clock signals;
driving a flip flop coupled to the last latch by the first clock signal; and
generating, by the filter, output data.

9. The method of claim 8, wherein each filter stage of the plurality of filter stages includes:
a plurality of coefficient multipliers respectively associated with the plurality of latches.

10. The method of claim 9, comprising:
receiving, by a coefficient multiplier of the plurality of coefficient multipliers, data over a primary input; and
multiplying, by the coefficient multiplier, the data by a coefficient.

11. The method of claim 8, wherein each filter stage of the plurality of filter stages includes:
a plurality of adders associated with the plurality of latches, respectively.

12. The method of claim 11, comprising:
adding, by an adder associated with a latch of the plurality of latches, an output of a preceding latch of the plurality of latches and primary input data to generate a sum; and
providing the sum to the latch associated with the adder.

13. The method of claim 8,
wherein the plurality of latches include:
a first latch,
the last latch, and
an intervening latch between the first latch and the last latch,
wherein the method comprises:
driving the first latch by a second clock signal; and
driving the intervening latch by a third clock signal, and
wherein an active time of the first clock signal is ahead of an active time of the second clock signal by a period of a fractional clock signal, and the active time of the second clock signal is ahead of an active time of the third clock signal by the period of the fractional clock signal.

14. A system comprising:
a data source configured to output data; and
a filter including:
a plurality of filter stages that are serially coupled, wherein each filter stage of the plurality of filter stages includes:
a plurality of latches respectively driven by a plurality of clock signals, wherein the plurality of clock signals are different from each other; and
a flip flop coupled to a last latch of the plurality of latches, wherein the flip flop and the last latch are driven by a first clock signal of the plurality of clock signals,
wherein the filter is configured to receive the data from the data source and generate filtered data.

15. The filter of claim 14, wherein each filter stage of the plurality of filter stages includes:
a plurality of coefficient multipliers respectively associated with the plurality of latches.

16. The filter of claim 15, wherein a coefficient multiplier of the plurality of coefficient multipliers multiplies data received over a primary input by a coefficient.

17. The filter of claim 14, wherein each filter stage of the plurality of filter stages includes:
a plurality of adders associated with the plurality of latches, respectively.

18. The filter of claim 17, wherein an adder of the plurality of adders, associated with a latch of the plurality of latches, is configured to:
add an output of a preceding latch of the plurality of latches and primary input data to generate a sum; and
provide the sum to the latch associated with the adder.

19. The filter of claim 14,
wherein the plurality of latches include:
a first latch driven by a second clock signal,
the last latch, and
an intervening latch between the first latch and the last latch, the intervening latch being driven by a third clock signal, and
wherein an active time of the first clock signal is ahead of an active time of the second clock signal by a period of a fractional clock signal, and the active time of the second clock signal is ahead of an active time of the third clock signal by the period of the fractional clock signal.

20. The filter of claim 14, wherein the filter includes:
a loading stage including:
a plurality of flip flops driven by the plurality of clock signals, respectively, wherein the plurality of flip flops load parallel data received by the plurality of flip flops to a plurality of coefficient multipliers.
